(19) United States
(12) Patent Application Publication
(10) Pub. No.: US 2016/0254421 A1
(43) Pub. Date: Sep. 1, 2016

(54) WHITE LIGHT EMITTING DEVICES INCLUDING BOTH RED AND MULTI-PHOSPHOR BLUE-SHIFTED-YELLOW SOLID STATE EMITTERS

(71) Applicant: Cree, Inc., Durham, NC (US)

(72) Inventor: Jesse Colin Reiherzer, Raleigh, NC (US)

(21) Appl. No.: 14/633,832

(22) Filed: Feb. 27, 2015

(51) Int. Cl. H01L 33/50; H01L 33/48; H01L 33/62; H01L 25/075

(52) U.S. Cl. CPC H01L 33/505; H01L 25/0753; H01L 33/486; H01L 33/501; H01L 33/62

(57) ABSTRACT

Light emitting devices include a red solid state emitter and a blue-shifted-yellow solid state emitter that comprises a blue light emitting diode (“LED”) and an associated luminophoric medium that includes first, second and third luminescent materials that emit light having a dominant wavelength in the respective green, yellow and red color ranges. Each blue-shifted-yellow solid state emitter emits light having a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295). These devices emit light having a color point that is within a 4-step MacAdam ellipse of the black-body locus.

### BACKGROUND

The present invention relates to light emitting devices and, more particularly, to light emitting devices that include multiple light emitting diodes (“LEDs”) and at least one luminophoric medium that together emit white light.

LEDs are solid state lighting devices or “emitters” that are capable of generating light. LEDs include both semiconductor-based LEDs and organic LEDs (which are often referred to as OLEDs). Semiconductor-based LEDs generally include a plurality of semiconductor layers that may be epitaxially grown on a semiconductor or non-semiconductor substrate such as, for example, sapphire, silicon, silicon carbide, gallium nitride or gallium arsenide substrates. One or more semiconductor p-n junctions are formed in these epitaxial layers. When a sufficient voltage is applied across the p-n junction, electrons in the n-type semiconductor layers and holes in the p-type semiconductor layers flow toward the p-n junction. As the electrons and holes flow toward each other, some of the electrons will recombine. Each time this occurs, a photon of light is emitted. The wavelength distribution of the light generated by an LED generally depends on the band-gap of the semiconductor materials used and the structure of the thin epitaxial layers that make up the “active area” of the device (i.e., the regions where the electrons and holes recombine).

The “peak” wavelength of an LED refers to the single wavelength where the radiometric emission spectrum of the LED reaches its maximum as detected by a photo-detector. An LED typically has a narrow wavelength distribution that is tightly centered about its “peak” wavelength. For example, the spectral power distributions of a typical LED may have a width of, for example, about 10-30 nm, where the width is measured at half the maximum illumination (referred to as the full-width-half-maximum or “FWHM” width). LEDs may also be identified by their “dominant” wavelength, which refers to the single wavelength of light which produces a color sensation most similar to the color sensation perceived from viewing light emitted by the light source (i.e., it is roughly akin to “hue”). The dominant wavelength differs from the peak wavelength in that the dominant wavelength takes into account the sensitivity of the human eye to different wavelengths of light.

White light refers to light that includes contributions from across the visible range of the radiometric spectrum. Incandescent and fluorescent light bulbs emit light that is generally perceived as white light, and white light is desirable for a wide range of lighting applications. As most LEDs are nearly monochromatic light sources that appear to emit light having a single color, a stand-alone LED is generally incapable of emitting white light.

In order to generate white light, multiple LEDs that emit light of different colors may be included in a light emitting device. When the light from these LEDs is mixed together (e.g., through a diffuser) it may be perceived as white light by a human observer. For example, by simultaneously energizing red, green and blue light emitting LEDs, the resulting combined light may appear white, or nearly white, depending on, for example, the relative intensities, peak wavelength and spectral power distributions of the source red, green and blue LEDs. A wide range of light is generally perceived as being white, or nearly white by a human observer, including, for example, “warm” white light which includes a larger proportion of orange and/or red light and “cool” white light which includes a larger proportion of purple and/or blue light.

White light may also be produced by surrounding a single-color LED with a luminescent material such as a phosphor that converts some of the light emitted by the LED to light of other colors. The phosphor is typically provided in the form of small particles that are mixed into a binder material that is then, for example, coated on the LED. The combination of the light emitted by the single-color LED that passes between the phosphor particles without conversion along with the light of one or more different colors that is emitted by the phosphor particles when excited by light from the blue LED may together produce a white or near-white light. For example, a single blue light emitting LED may be used in combination with a yellow phosphor, polymer or dye such as, for example, cerium-doped yttrium aluminum garnet (which has the chemical formula Y₃Al₅O₁₂:Ce, which is referred to herein as a “YAG:Ce” phosphor) that “down-converts” some of the blue light emitted by the LED to light having a longer wavelength, changing its color to yellow. In a blue LED/yellow phosphor lamp, the blue LED produces an emission with a dominant wavelength of, for example, about 450-460 nanometers, and the phosphor produces yellow fluorescence with a peak wavelength of, for example, about 560 nanometers in response to the blue emission. Some of the blue light passes through the phosphor (and/or between the phosphor particles) without being down-converted, while a substantial portion of the light is absorbed by the phosphor, which becomes excited and emits longer wavelength light that has a peak wavelength in the yellow color range (i.e., the blue light is down-converted to yellow light). The phosphor may emit light over a large range of wavelengths (e.g., have a FWHM width of 80 nm or more), so that while the phosphor may have its peak emission in the yellow color range, it will also emit light in, for example the green and red color ranges. The combination of blue light from the LED that passes through the phosphor without conversion along with the yellow and other color light that is emitted by the phosphor particles may appear white to an observer. Such light is typically perceived as being cool white in color. In another approach, light from a violet or ultraviolet emitting LED may be converted to white light by surrounding the LED with multicolor phosphors or dyes. In either case, red-emitting phosphor particles may also be added to improve the color rendering properties of the light, i.e., to make the light appear more “warm,” particularly when the single color LED emits blue or ultraviolet light.

### SUMMARY

Pursuant to some embodiments of the present invention, light emitting devices are provided that include a first group of at least one blue-shifted-yellow solid state emitter and a second group of at least one red solid state emitter that emits light having a dominant wavelength in the red color range. Each blue-shifted-yellow solid state emitter comprises a blue LED that, when excited, emits light having a peak wavelength in the blue color range, and an associated luminophoric medium. The luminophoric medium includes first, second and third luminescent materials that, when excited by light from the blue LED, emit light having dominant wavelengths in respective green, yellow and red color ranges. Each blue-shifted-yellow solid state emitter emits light having a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295). The light emitted by the combination of the first group of at least one blue-shifted-yellow solid state emitter and the second group of at least one red solid state emitter has a color point that is within a 4-step MacAdam ellipse of the black-body locus on the 1931 CIE Chromaticity Diagram.

In some embodiments, the blue LED emits light may have a peak wavelength of less than 455 nanometers. The color temperature of the light emitted by the combination of the first group of at least one blue-shifted-yellow solid state emitter and the first group of at least one red solid state emitter may be less than 5500K. In some embodiments, Each blue-shifted-yellow solid state emitter may emit light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361)

In some embodiments, the dominant wavelength of the third luminescent material may be greater than the dominant wavelength of the at least one red solid state emitter. The third luminescent material may have a full-width-half-maximum width that is less than the full-width-half-maximum width of the at least one red solid state emitter.

In some embodiments, a weight of the third luminescent material may be less than ten percent of a sum of the weights of the first, second and third luminescent materials. In other embodiments, a weight of the first luminescent material may be between 20 and 50 percent of a sum of the weights of the first, second and third luminescent materials, a weight of the second luminescent material may be between 50 and 70 percent of the sum of the weights of the first, second and third luminescent materials, and a weight of the third luminescent material may be less than 5 percent of the sum of the weights of the first, second and third luminescent materials

In some embodiments, the first luminescent material may be a YₐCe_{b}Al_{c}Ga_{d}O_{z} phosphor or a LuAG:Ce phosphor, and the second luminescent material may be a Y₃Al₅O₁₂:Ce phosphor. The luminophoric medium may include a silicone binder and may be coated directly onto the blue LED, and the blue LED may be mounted in flip-chip configuration on a submount.

In some embodiments, the blue LED may emit light having a peak wavelength of less than 455 nanometers, the dominant wavelength of the third luminescent material may be greater than the dominant wavelength of the at least one red solid state emitter, the color temperature of the light emitted by the combination of the first group of at least one blue-shifted-yellow solid state emitter and the first group of at least one red solid state emitter may be less than 5500K, each blue-shifted-yellow solid state emitter may emit light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361), and a weight of the first luminescent material may be between 20 and 50 percent of a sum of the weights of the first, second and third luminescent materials, a weight of the second luminescent material may be between 50 and 70 percent of the sum of the weights of the first, second and third luminescent materials, and a weight of the third luminescent material may be less than 5 percent of the sum of the weights of the first, second and third luminescent materials.

Pursuant to further embodiments of the present invention, light emitting devices are provided that include a first group of at least one blue-shifted-yellow solid state emitter and a second group of at least one red solid state emitter that emits light having a dominant wavelength in the red color range. Each blue-shifted-yellow solid state emitter comprises a blue LED that, when excited, emits light having a peak wavelength in the blue color range, and an associated luminophoric medium that includes at least first and second luminescent materials that, when excited by light from the blue LED, emit light having dominant wavelengths in respective first and second color ranges. The first and second color ranges are different color ranges selected from the group of a green color range, a yellow color range and a red color range. Each blue-shifted-yellow solid state emitter emits light having a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295). The light emitted by the combination of the first group of at least one blue-shifted-yellow solid state emitter and the second group of at least one red solid state emitter has a color point that is within a 4-step MacAdam ellipse of the black-body locus on the 1931 CIE Chromaticity Diagram.

In some embodiments, the blue LED may emit light having a peak wavelength of less than 450 nanometers.

In some embodiments, the first color range may be the green color range and the second color range may be the yellow color range, and the associated luminophoric medium for each blue-shifted-yellow solid state emitter may further include a third luminescent material that, when excited by light from the blue LED, emits light having a dominant wavelength in the red color range. In other embodiments, the first color range may be the green color range and the second color range may be the red color range. In still other embodiments, the first color range may be the green color range and the second color range may be the yellow color range.

In some embodiments, the color temperature of the light emitted by the combination of the at least one phosphor-converted LED and the at least one red LED may be less than 5500K.

In some embodiments, the second luminescent materials may comprise less than ten percent by weight of the luminescent materials included in the luminophoric medium.

In some embodiments, each blue-shifted-yellow solid state emitter may emit light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361) and an amount of the first luminescent material that is included in the luminophoric medium may less than an amount of the second luminescent material that is included in the luminophoric medium, by weight.

In some embodiments, the luminophoric medium may include a silicone binder and may be coated directly onto the blue LED, and the blue LED may be mounted in flip-chip configuration on a submount. Each blue-shifted-yellow solid state emitter may emit light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361) and an amount of the first luminescent material that is included in the luminophoric medium may be less than half an amount of the second luminescent material that is included in the luminophoric medium, by weight.

In some embodiments, the first color range may be the green color range, the first luminescent materials may comprise at least seventy percent by weight of the total luminescent materials included in the luminophoric medium, and each blue-shifted-yellow solid state emitter may emit light having a color point on the 1931 CIE Chromaticity Diagram in a region defined by ccx, ccy coordinates of (0.226, 0.295), (0.295, 0.298), (0.375, 0.472), (0.506, 0.303), (0.226, 0.295).

Pursuant to still further embodiments of the present invention, phosphors for use with light emitting devices are provided that include a first group of at least one blue-shifted-yellow solid state emitter and a second group of at least one red solid state emitter that emits light having a dominant wavelength in the red color range. Each blue-shifted-yellow solid state emitter comprising a blue LED that, when excited, emits light having a peak wavelength in the blue color range, and an associated luminophoric medium that includes at least first and second luminescent materials that, when excited by light from the blue LED, emits light having dominant wavelengths in the respective green and red color ranges. Each blue-shifted-yellow solid state emitter emits light having a color point on the 1931 CIE Chromaticity Diagram in a region defined by ccx, ccy coordinates of (0.226, 0.295), (0.295, 0.298), (0.375, 0.472), (0.506, 0.303), (0.226, 0.295). The light emitted by the combination of the first group of at least one blue-shifted-yellow solid state emitter and the second group of at least one red solid state emitter has a color point that is within a 4-step MacAdam ellipse of the black body locus on the 1931 CIE Chromaticity Diagram.

In some embodiments, the blue LED may emit light having a peak wavelength of less than 455 nanometers.

In some embodiments, the dominant wavelength of the second luminescent material may be greater than the dominant wavelength of the red solid state emitter.

In some embodiments, the color temperature of the light emitted by the combination of the at least one blue-shifted-yellow solid state emitter and the at least one red LED may be less than 5500K. The second luminescent materials may comprise less than ten percent by weight of the sum of the first and second luminescent materials.

### BRIEF DESCRIPTION OF THE DRAWINGS

FIG. 1 is a graph of a 1931 CIE Chromaticity Diagram illustrating the location of the black-body locus.

FIG. 2 is a graph of the blue-shifted-yellow region of the 1931 CIE Chromaticity Diagram.

FIG. 3 is an enlarged view of a portion of the 1931 CIE Chromaticity Diagram that illustrates the possible color points for blue-shifted-yellow solid state emitters that include blue LEDs having various peak wavelengths and a luminophoric medium that includes a YAG:Ce phosphor.

FIG. 4 is another enlarged view of a portion of the 1931 CIE Chromaticity Diagram that illustrates how the inclusion of green light emitting, yellow light emitting and/or red light emitting luminescent materials in the luminophoric medium for a blue-shifted-yellow solid state emitter may affect the color point of the blue-shifted-yellow solid state emitter.

FIG. 5 is a graph of the radiometric spectrum for a light emitting device that includes a conventional blue-shifted-yellow solid state emitter that has an associated luminophoric medium that includes a yellow YAG:Ce phosphor and a red solid state emitter.

FIGS. 6A-6C are schematic cross-sectional views of blue-shifted-yellow solid state emitters according to certain embodiments of the present invention.

FIG. 7 is a graph illustrating the emission spectra of two example light emitting devices according to embodiments of the present invention as compared to the emission spectrum of a light emitting device that includes a conventional blue-shifted-yellow solid state emitter.

FIGS. 8A and 8B are a top perspective view and a top view, respectively, of a light emitting device according to certain embodiments of the present invention.

FIG. 9 is a schematic circuit diagram of a light emitting device according to embodiments of the present invention.

### DETAILED DESCRIPTION

Solid state emitters according to embodiments of the present invention may include III-V nitride (e.g., gallium nitride) based LEDs fabricated on a silicon carbide, sapphire or gallium nitride substrates that emit blue light such as, for example, LEDs manufactured and sold by Cree, Inc. of Durham, N.C. Such LEDs may (or may not) be configured to operate such that light emission occurs through the substrate in a so-called “flip chip” orientation. Solid state emitters according to embodiments of the present invention include both vertical devices with a cathode contact on one side of the LED, and an anode contact on an opposite side of the LED and devices in which both contacts are on the same side of the LED.

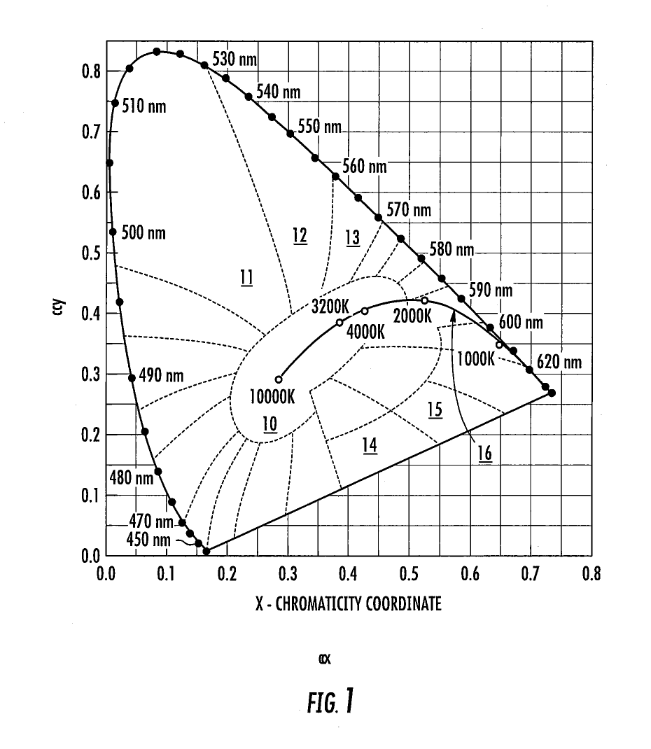

Visible light may include light having a single wavelength or light that is a combination of multiple wavelengths. The apparent color of visible light can be illustrated with reference to a two-dimensional chromaticity diagram, such as the 1931 CIE Chromaticity Diagram illustrated in FIG. 1. The 1931 CIE Chromaticity Diagram is an international standard for primary colors that was established in 1931 that provides a useful reference for defining colors as weighted sums of colors. For a technical description of CIE chromaticity diagrams, see, for example, “Encyclopedia of Physical Science and Technology”, vol. 7, 230 231 (Robert A Meyers ed., 1987). The diagram encompasses all of the hues perceived by the human eye.

As shown in FIG. 1, colors on a 1931 CIE Chromaticity Diagram are defined by ccx and ccy coordinates, which are sometimes referred to as chromaticity coordinates, that fall within a generally U-shaped area. Each point on the diagram defined by a pair of chromaticity coordinates (ccx, ccy) is referred to as a “color point” and corresponds to a particular hue of light. Colors on or near the outer edge of the U-shaped area are saturated colors composed of light having a single wavelength, or a very small wavelength distribution. Colors on the interior of the area are unsaturated colors that are composed of a mixture of different wavelengths.

White light, which can be a mixture of many different wavelengths, is generally found near the middle of the diagram, in the region labeled 10 in FIG. 1. There are many different hues of light that may be considered “white,” as evidenced by the size of the region 10. For example, some “white” light, such as light generated by sodium vapor lighting devices, may appear yellowish in color, while other “white” light, such as light generated by some fluorescent lighting devices, may appear more bluish in color. Light that generally appears green or includes a substantial green component is plotted in the regions 11, 12 and 13 that are above the white region 10, while light below the white region 10 generally appears pink, purple or magenta. For example, light plotted in regions 14 and 15 of FIG. 1 generally appears magenta (i.e., red-purple or purplish red).

In the 1931 CIE Chromaticity Diagram, deviation from a point on the diagram can be expressed either in terms of the ccx, ccy coordinates or, alternatively, in order to give an indication as to the extent of the perceived difference in color, in terms of MacAdam ellipses. For example, a locus of points defined as being a specified number of MacAdam ellipses from a specified hue defined by a particular color point on the diagram consists of hues which would each be perceived as differing from the specified hue to a common extent.

A binary combination of light from two different light sources may appear to have a different color than either of the two constituent colors. The color of the combined light may depend on the wavelengths and relative intensities of the two light sources. For example, light emitted by a combination of a blue source and a red source may appear purple or magenta to an observer. Similarly, light emitted by a combination of a blue source and a yellow source may appear white to an observer.

As shown in FIG. 1 a locus of color points on the 1931 CIE Chromaticity Diagram exists that is referred to as the “black-body” locus 16. The black body locus 16 corresponds to the location of color points of light emitted by a black-body radiator that is heated through a continuous range of temperatures. The black-body locus 16 is also referred to as the “planckian” locus because the chromaticity coordinates (i.e., color points) that lie along the black-body locus 16 obey Planck's equation: E(λ)=A λ⁻⁵/(e^{B/T}−1), where E is the emission intensity, λ, is the emission wavelength, T is the color temperature of the black-body radiator and A and 13 are constants. Color coordinates that lie on or near central portions of the black-body locus 16 may yield pleasing white light to a human observer.

In FIG. 1, the temperature at which a black-body radiator must be heated to emit light having various color points is shown. These temperature listings show the color path of a blackbody radiator that is caused to increase to such temperatures. As can be seen in FIG. 1, at lower temperatures (e.g., 2000-3500K) the color points are closer to the red and orange regions of the 1931 CIE Chromaticity Diagram, while at higher temperatures (e.g., 5000-10,000K) the color points are closer to the blue region of the diagram. This follows because when a heated object becomes incandescent, it first glows reddish, then yellowish, then white, and finally blueish. The above-described change in color with temperature occurs because the wavelength associated with the peak radiation of the black-body radiator becomes progressively shorter with increased temperature, consistent with the Wien Displacement Law. Illuminants which produce light which is on or near the black-body locus 16 can thus be described in terms of their correlated color temperature (“CCT”), which is often referred to simply as “color temperature.” The “color temperature” of light on or near the black-body locus 16 refers to the point on the black-body locus 16 where a black-body radiator will emit light having that particular hue when heated to the color temperature.

As used herein, the term “white light” refers to light that is perceived as white, is within a 7-step MacAdam ellipse of the black-body locus 16 on the 1931 CIE Chromaticity Diagram, and has a color temperature ranging from 2000K to 10,000K. White light with a color temperature of 4000K may appear yellowish in color, while white light with a color temperature of 8000K or more may appear more bluish in color, and may be referred to as “cool” white light. “Warm” white light may be used to describe white light with a color temperature of between about 2500K and 4500K, which is more reddish or yellowish in color. Warm white light is generally a pleasing color to a human observer. Warm white light with a color temperature of 2500K to 3300K may be preferred for certain applications.

The ability of a light source to accurately reproduce color in illuminated objects is typically characterized using the color rendering index (“CRI Ra” or “CRI”). The CRI of a light source is a modified average of the relative measurements of how the color rendition of an illumination system compares to that of a reference black-body radiator when illuminating eight reference colors that are referred to as R1 through R8. Thus, the CRI is a relative measure of the shift in surface color of an object when lit by a particular lamp. The CRI equals 100 if the color coordinates of a set of test colors being illuminated by the illumination system are the same as the coordinates of the same test colors being irradiated by the black-body radiator. Daylight generally has a CRI of nearly 100, incandescent bulbs have a CRI of about 95, fluorescent lighting typically has a CRI of about 70 to 85, while monochromatic light sources have a CRI of essentially zero. Light sources for general illumination applications with a CRI of less than 50 are generally considered very poor and are typically only used in applications where economic issues preclude other alternatives. Light sources with a CRI value between 70 and 80 have application for general illumination where the colors of objects are not important. For many general interior illumination applications, a CRI value of greater than 80 is acceptable. A light source with color coordinates within a 4-step MacAdam ellipse of the black-body locus 16 and a CRI value that exceeds 85 is more suitable for general illumination purposes. Light sources with CRI values of more than 90 provide greater color quality and are desired in many applications including, for example, lighting for homes and lighting for retail settings.

For backlight, general illumination and various other applications, it is often desirable to provide a lighting source that generates white light having a relatively high CRI, so that objects illuminated by the lighting source may appear to have more natural coloring to the human eye. Accordingly, such lighting sources may typically include an array of solid state lighting devices including red, green and blue light emitting devices that generate a combined light that may appear white, or nearly white, depending on the color points and relative intensities of the red, green and blue sources. However, even light that is a combination of red, green and blue emitters may have a low CRI, particularly if the emitters generate saturated light, because such light may lack contributions from many visible wavelengths.

As noted above, CRI is an average color rendering value for eight specific sample colors that are generally referred to as R1-R8. Additional sample colors R9-R15 are also often used in evaluating the color rendering properties of a light source. The sample color R9 is the saturated red color, and it is generally known that the ability to reproduce red colors well is key for accurately rendering colors, as the color red is often found mixed into processed colors. Accordingly, all else being equal, lamps with high R9 values tend to produce the most vivid colors. Light emitting devices having high R9 values (e.g., R9 values of 90 or more) are desirable in a wide number of lighting applications.

Another important performance parameter for an LED lighting source is the intensity of the light emitted, which is referred to as the radiant flux of the device. However, as the human eye has varying sensitivity to different wavelengths of light, the intensity of the light emitted by a lighting source is most typically measured in terms of the lighting source's “luminous flux,” which is a measure of the power of the light emitted by a light source as perceived by a human observer. The luminous flux of a light source is typically measured in lumens (lm). The luminous flux of a light source differs from the radiant flux of the light source in that the radiant flux measures the total power emitted, while the luminous flux weights the power of the light emitted at each wavelength based on a luminosity function which represents the response of the human eye for each different wavelength. The human eye has the greatest sensitivity to light that is at a wavelength of about 555 nm, which is in the middle of the wavelengths representing the visible light range.

Because of the varying sensitivity of the human eye to light of different wavelengths, there tends to be a tradeoff between the intensity of the light emitted by an LED-based lighting source and the CRI of the light emitted. For example, since the human eye is most sensitive to light at a wavelength of about 555 nm, a monochromatic light source at 555 nm will exhibit a high luminous flux value, but will have a CRI of nearly zero. In order to obtain high CRI values, it is generally necessary to have light contribution across a wide range of wavelengths, including wavelengths that are relatively far away from 555 nm where the peak sensitivity of light to the human eye occurs. Because the human eye has reduced sensitivity to the wavelengths on either end of the visible light spectrum, the light contributions that are often added to improve the CRI of a device may result in a decrease in the luminous flux of the device. Another closely-related performance parameter for an LED-based lighting source is its luminous efficiency, which is typically measured in lumens/watt.

Pursuant to embodiments of the present invention, light emitting devices are provided that may exhibit high luminous efficiency values while maintaining good color rendering properties such as, for example, CRI values exceeding 90. These light emitting devices may include a first group of at least one blue-shifted-yellow solid state emitter and a second group of at least one red solid state emitter. Each blue-shifted-yellow solid state emitter includes an LED that emits light having a peak wavelength in the blue color range (referred to herein as a “blue LED”) and an associated luminophoric medium that includes at least first and second luminescent materials. These first and second luminescent materials, when excited by light emitted by the blue LED, emit light having dominant wavelengths in respective first and second color ranges, wherein the first and second color ranges are different color ranges selected from the group of a green color range, a yellow color range and a red color range. Each blue-shifted-yellow solid state emitter is designed so that the combination of the light emitted by the blue LED and the first and second luminescent materials has a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295). Herein, the region of the 1931 CIE Chromaticity Diagram that is defined by the above-specified coordinates is referred to as the “blue-shifted-yellow region” of the diagram. This region of the 1931 CIE Chromaticity Diagram is located above the black-body locus 16 except for a small portion of the region that falls on or below the portion of the black-body locus 16 corresponding to very high color temperatures (e.g., color temperatures of about 7500K or more). Each red solid state emitter emits light having a dominant wavelength in the red color range. The light emitted by the combination of the first group of at least one blue-shifted-yellow solid state emitter and the second group of at least one red solid state emitter has a color point that is within a 4-step MacAdam ellipse of a color point on the black-body locus 16 on the 1931 CIE Chromaticity Diagram that has a color temperature of less than 5500K.

For purposes of the present disclosure, the blue, green, yellow and red color ranges discussed above are defined as follows:

Blue Color Range—Wavelength between 430 nm and 485 nm;

Green Color Range—Wavelengths between 500 nm and 559 nm

Yellow Color Range—Dominant wavelengths between 560 nm and 599 nm

Red Color Range—Dominant wavelengths between 600 nm and 660 nm

In some embodiments, the first luminescent material may, when excited by light from the blue LED, emit light having a dominant wavelength in the green color range, and the second luminescent material may, when excited by light from the blue LED, emit light having a dominant wavelength in either the yellow color range or the red color range. In some cases, three different luminescent materials may be included in the luminophoric medium, namely one each of luminescent materials that, when excited by light from the blue LED, emit light in the respective green, yellow and red color ranges. The light emitting devices according to embodiments of the present invention may exhibit improved CRI and luminous efficiency performance as compared to conventional light emitting devices, as will be discussed in greater detail below.

So-called blue-shifted-yellow solid state emitters are known in the art. A blue-shifted-yellow solid state emitter refers to a blue LED that has an associated luminophoric medium that includes luminescent materials. The combined light output of the blue LED and the light emitted by the luminescent materials when excited by light from the blue LED has a color point within the above-defined “blue-shifted-yellow region” of the 1931 CIE Chromaticity Diagram that generally lies above and/or to the left of the portion of the black-body locus 16 that corresponds to color temperatures of 5500K or less. Color points within the blue-shifted-yellow region are generally perceived as having a yellow or yellowish-green color. For example, U.S. Pat. No. 7,213,940 (“the '940 patent”), which is assigned to the assignee of the present application, discloses light emitting devices that include a blue-shifted-yellow solid state emitter that includes a blue LED and a luminophoric medium that includes a yellow YAG:Ce phosphor. The '940 patent teaches that the blue LED may have a peak wavelength in the range of 450-465 nm and that the color point of the blue-shifted-yellow solid state emitters falls within a region in the 1931 CIE Chromaticity Diagram defined by ccx, ccy coordinates of (0.32, 0.40), (0.36, 0.48), (0.43, 0.45), (0.42, 0.42), (0.36, 0.38), (0.32, 0.40). It should be noted that the region discussed in the '940 patent as a blue-shifted-yellow region only partially overlaps the blue-shifted-yellow region defined in the present application. The '940 patent teaches combining the blue-shifted-yellow solid state emitters with red solid state emitters to provide a light emitting device that emits white light having luminous efficiency values of as high as 80 lumens per watt and CRI values as high as 92. The light emitting devices of the '940 patent may provide better color rendering performance than light emitting devices that include separate blue, green and red LEDs, and may exhibit better luminous efficiency performance that light emitting devices which use various combinations of blue, cyan, green, yellow, orange and/or red luminescent materials to generate white light.

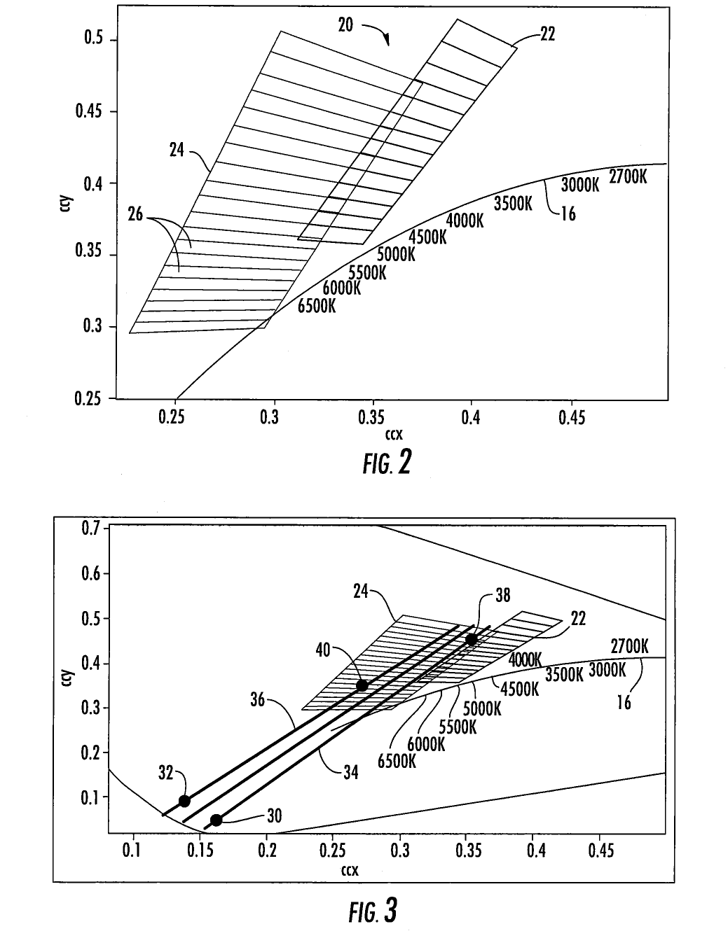

As noted above, as defined herein, the blue-shifted-yellow region of the 1931 CIE Chromaticity Diagram is defined by ccx, ccy coordinates (0.226, 0.295), (0.295, 0.298), (0.323, 0.360), (0.344, 0.358), (0.422, 0.496), (0.391, 0.517), (0.371, 0.477), (0.506, 0.303), (0.226, 0.295). This blue-shifted-yellow region includes two sub-regions that are referred to herein as an x-bin and a y-bin. The x-bin and the y-bin overlap slightly. The x-bin is defined by ccx, ccy coordinates (0.311, 0.361), (0.344, 0.358), (0.422, 0.496), (0.391, 0.517), (0.311, 0.361), and the y-bin is defined by ccx, ccy coordinates of (0.226, 0.295), (0.295, 0.298), (0.375, 0.472), (0.506, 0.303), (0.226, 0.295). FIG. 2, is an enlarged view of a portion of the 1931 CIE Chromaticity Diagram that illustrates the blue-shifted-yellow region 20 of the 1931 CIE Chromaticity Diagram along with the x-bin 22 and the y-bin 24 of the blue-shifted-yellow region 20. As is also shown in FIG. 2, the x-bin 22 and the y-bin 24 are further sub-divided into a plurality of individual color bins 26.

As discussed above, the conventional approach for providing a blue-shifted-yellow solid state emitter is to coat a blue LED with a yellow YAG:Ce phosphor. YAG:Ce phosphors are well known in the art and are routinely used in luminophoric mediums given their high efficiency, relatively low cost, broad spectrum and dominant wavelength in a desirable range for emitting white light. Typically, a YAG:Ce phosphor will exhibit a dominant wavelength of about 560-570 nm. The dominant wavelength may be varied within this range (or even outside this range) by changing the Ce concentration, the particle sizes and the like. The Ce concentration and the particle size of a yellow YAG:Ce phosphor are typically selected based on luminous efficiency considerations to provide an efficient, bright solid state emitter. In other words, because of luminous efficiency considerations, the color point for the yellow YAG:Ce phosphor may be set at a certain point.

FIG. 3 is an enlarged view of a portion of the 1931 CIE Chromaticity Diagram that illustrates the color points for two blue-shifted-yellow solid state emitters that each comprise a blue LED and a luminophoric medium that includes a YAG:Ce phosphor. As discussed above, the color point of the YAG:Ce phosphor may be set based on, for example, luminous efficiency considerations. If this is the case, then the color point of the YAG:Ce phosphor may be fixed, and cannot be varied to adjust the color point of the blue-shifted-yellow solid state emitters. In the example of FIG. 3, it has been assumed that the color point of the YAG:Ce phosphor has a fixed value that was chosen based on luminous efficiency considerations (note that the color point for the YAG:Ce phosphor is not depicted FIG. 3 as it falls outside the portion of the 1931 CIE Chromaticity Diagram that is illustrated, but will fall at the intersection of the two tie lines 34, 36).

FIG. 3 illustrates how the color points for two separate blue-shifted-yellow solid state emitters may be set. The first of these blue-shifted-yellow solid state emitters has a blue LED that emits light having a peak wavelength of 455 nm. The color point for the light emitted by this blue LED is designated as point 30 in FIG. 3. The second of the blue-shifted-yellow solid state emitters has a blue LED that emits light having a peak wavelength of 465 nm. The color point for the light emitted by this blue LED is designated as point 32 in FIG. 3. Two tie lines 34, 36 are also depicted in FIG. 3 which connect the color points 30, 32 of the blue LEDs to the color point of the YAG:Ce phosphor (which is not visible in FIG. 3). A third tie line (unnumbered) is shown between tie lines 34, 36 that represents the tie line for a blue-shifted-yellow solid state emitter that has a blue LED that emits light having a peak wavelength of 460 nm. The color points 38, 40 of the combined light emitted by each blue LED and its associated YAG:Ce phosphor will fall somewhere along the respective tie lines 34, 36 that connect the color points 30, 32 of the blue LEDs to the color point of the YAG:Ce. The precise location of the color points 38, 40 of the combined light output is determined based on the relative intensity of the blue LED as compared to the intensity of the light emitted by the associated YAG:Ce phosphor.

Referring to FIG. 3, the color point 30, 32 for each blue LED will be based on the peak wavelength of the blue LED, as the blue LED will emit light having a generally uniform and very tight distribution about the peak wavelength. Blue LEDs having peak wavelengths in the range of approximately 450 nm to about 465 nm may have tie lines 34, 36 with the YAG:Ce phosphor that generally run through the x-bin 22 portion of the blue-shifted-yellow region 20, while blue LEDs having peak wavelengths of about 455 nm to about 485 nm may have tie lines 34, 36 with the YAG:Ce phosphor that generally run through the y-bin 24 portion of the blue-shifted-yellow region 20. As a result, to provide blue LEDs that are to be combined with a yellow YAG:Ce phosphor to target color points in the blue-shifted-yellow region 20 of the 1931 CIE Chromaticity Diagram, it is typically necessary to provide blue LEDs having a peak wavelength of 450 nm or higher to target the x-bin 22, and 455 nm or higher to target the y-bin 24. This may be achieved, for example, by targeting a peak wavelength of between 460-465 nm during the LED growth process. Due to the vagaries of the LED growth process which results in varying peak wavelengths for different growth runs and even across the same growth wafer, this may result in a distribution of blue LEDs that are suitable for providing LEDs for targeting the x-bin 22 and the y-bin 24.

All else being equal, blue LEDs having shorter peak wavelengths (e.g., peak wavelengths of less than 460 nm) tend to have, on average, higher radiant flux values than blue LEDs having longer peak wavelengths (e.g., wavelengths in the range of about 460 nanometers to about 485 nanometers). Moreover, the increase in radiant flux provided by the shorter wavelength blue LEDs is typically greater than the decrease in the response of the human eye to the shorter wavelength blue light. Thus, higher luminous efficiency values are typically obtainable when lower wavelength blue LEDs are used to fabricate blue-shifted-yellow solid state emitters. Unfortunately, however, as shown in FIG. 3, it may not be possible to use such short wavelength blue LEDs and still target the blue-shifted-yellow region 20 when certain high efficiency YAG:Ce phosphors are used in the luminophoric medium, as the tie lines 34, 36 between the color point for the YAG:Ce phosphor and the color points of the short wavelength blue LEDs fall outside many if not most or all of the sub bins in the x-bin 22 and/or y-bin 24 portions of the blue-shifted-yellow region 20. While one potential way to form blue-shifted-yellow solid state emitters using shorter wavelength blue LEDs is to adjust the composition of the YAG:Ce phosphor to move the color point thereof farther up on the 1931 CIE Chromaticity Diagram, such a change may negatively impact the efficiency or other characteristics of the phosphor, and, in any event, may not move the color point far enough to use blue LEDs having very short peak wavelengths.

A conventional blue-shifted-yellow solid state emitter may also potentially be used with a short wavelength blue LED and an appropriately selected red solid state emitter to target color points in the x-bin 22 and/or the y-bin 24. However, when such an approach is used, the CRI of the light emitting device is likely to be between 80 and 90, which may be considered unacceptable for various applications.

In addition to improved luminous efficiency and/or improved color rendering, various other considerations may also make it desirable to use shorter wavelength blue LEDs. For example, blue LEDs having shorter peak wavelengths may also tend to exhibit an improved hot/cold brightness ratio as compared to blue LEDs having longer peak wavelengths. The hot/cold brightness ratio refers to the brightness of the LED as measured at a high temperature (e.g., 85° C.) as compared to the brightness of the LED as measured at a lower temperature (e.g., 25° C.). Lower hot/cold brightness ratios are desired as they indicate that the LED operates more consistently as a function of operating temperature, which allows the device to provide more consistent color rendering. The use of shorter wavelength blue LEDs may also be desirable for manufacturing efficiency, as shorter wavelength blue LEDs will likely be produced for applications other than the formation of blue-shifted-yellow solid state emitters (e.g., for blue LEDs that are used for blue lighting applications, for applications using a blue LED and one or more phosphors to emit white light, etc.) due to the performance advantages of shorter wavelength blue LEDs, and thus manufacturing may be simplified if it is not necessary to intentionally manufacture longer wavelength blue LEDs for blue-shifted-yellow solid state emitter applications.

Pursuant to embodiments of the present invention, blue-shifted-yellow solid state emitters are provided that comprise at least one blue LED and an associated luminophoric medium that has more than one different type of luminescent material therein. The blue-shifted-yellow solid state emitters according to embodiments of the present invention may be combined with at least one red solid state emitter to provide a light emitting device that emits white light having a color point on or near the black-body locus 16. The blue LED may have a relatively low peak wavelength such as a wavelength of less than about 450 nm. The blue-shifted-yellow solid state emitters according to embodiments of the present invention may be designed to emit white light having a correlated color temperature of less than 5500K.

In some embodiments, the luminophoric medium that is used in the blue-shifted-yellow solid state emitters may include a first luminescent material such as, for example, a Lu₃Al₅O₁₂:Ce phosphor (herein referred to as a “LuAG:Ce phosphor”) or a YₐCe_{b}Al_{c}Ga_{d}O_{z} phosphors (herein referred to as a “gallium-substituted YAG:Ce phosphor”) that, when excited by light emitted by a blue LED, emits light having a dominant wavelength in the green color range, and a second luminescent material such as, for example, a red (Ca_{1-x-y}SrₓEu²⁺_{y})SiAlN₃ phosphor or red quantum dots that, when excited by light emitted by a blue LED, emits light having a dominant wavelength in the red color range. In other embodiments, the luminophoric medium that is used in the blue-shifted-yellow solid state emitters may include a first luminescent material that, when excited by light emitted by a blue LED, emits light having a dominant wavelength in the green color range, a second luminescent material such as, for example, a YAG:Ce phosphor that, when excited by light emitted by a blue LED, emits light having a dominant wavelength in the yellow color range and a third luminescent that, when excited by light emitted by a blue LED, emits light having a dominant wavelength in the red color range. In still other embodiments, the luminophoric medium that is used in the blue-shifted-yellow solid state emitters may include a first luminescent material that, when excited by light emitted by a blue LED, emits light having a dominant wavelength in the green color range, and a second luminescent material that, when excited by light emitted by a blue LED, emits light having a dominant wavelength in the yellow color range.

As noted above, in some embodiments, a gallium-substituted YAG:Ce phosphor may be used as the green luminescent material as such phosphors may absorb more light at the lower wavelengths in the blue color range as compared to the above-described LuAG:Ce phosphor. This may be advantageous, as the shorter wavelength blue light may not contribute very much to the CRI of the device, while the longer wavelength blue light will tend to pass through at a higher rate. Additionally, the gallium substituted YAG:Ce phosphors may have generally higher emission in the cyan and low wavelength green color ranges as compared to a LuAG:Ce phosphor, and the gallium substituted YAG:Ce phosphor may down-convert a greater percentage of the light emitted by the blue LED. This may tend to smooth out the emission spectra in the lower wavelength ranges, which may generally tend to result in improved CRI performance.

As noted above, the blue-shifted-yellow solid state emitters that are used in light emitting devices according to embodiments of the present invention have an associated luminophoric medium that includes at least two different luminescent materials. Herein, a “luminescent material” refers to a material, such as a phosphor, that absorbs light having first wavelengths and re-emits light having second wavelengths that are different from the first wavelengths, regardless of the delay between absorption and re-emission and regardless of the wavelengths involved. For example, “down-conversion” luminescent materials may absorb light having shorter wavelengths and re-emit light having longer wavelengths. A wide variety of luminescent materials are known, with exemplary materials being disclosed in, for example, U.S. Pat. No. 6,600,175 and U.S. Patent Application Publication No. 2009/0184616. In addition to phosphors, other luminescent materials include scintillators, day glow tapes, nanophosphors, quantum dots, fluorescent materials, phosphorescent materials and inks that glow in the visible spectrum upon illumination with (e.g., ultraviolet) light.

Herein, a “green luminescent material” or a “green phosphor” refers to a luminescent material or phosphor that emits light having a dominant wavelength in the green color range (when, for example, excited by the blue or ultraviolet LED light source), a “yellow luminescent material” or a “yellow phosphor” refers to a luminescent material or phosphor that emits light having a dominant wavelength in the yellow color range (when, for example, excited by the blue or ultraviolet LED light source), and a “red luminescent material” or “red phosphor” refers to a luminescent material or phosphor that emits light having a dominant wavelength in the red color range (when, for example, excited by the blue or ultraviolet LED light source).

Herein, the term “luminophoric medium” refers to a medium which includes one or more luminescent materials. The medium that includes the luminescent materials may comprise, for example, a clear encapsulant such as an epoxy-based or silicone-based curable resin. A luminophoric medium is “associated” with a light emitting element such as an LED if it is configured to receive light from the LED so that the received light will excite the luminescent materials in the luminophoric medium and cause the luminescent materials to emit light of other colors. The luminophoric medium may be coated onto the LED (e.g., a conformal coating), used to fill an optical cavity that includes the LED, be coated on a lens or other element that is provided above or below the LED, arranged to receive light from a reflective surface that receives light from an LED, etc. The luminophoric medium may comprise a single layer or multiple layers, which may or may not be in direct contact with each other or with the LED.

Embodiments of the present invention will now be described in more detail with reference to FIGS. 4-9, in which example embodiments of the present invention are shown.

FIG. 4 is another enlarged view of a portion of the 1931 CIE Chromaticity Diagram that illustrates how inclusion of green, yellow and/or red luminescent materials in the luminophoric medium for the blue-shifted-yellow solid state emitters may affect the color point of the blue-shifted-yellow solid state emitters. As shown in FIG. 4, the light emitted by a conventional blue-shifted-yellow solid state emitter that comprises a blue LED with an associated luminophoric medium having a YAG:Ce phosphor will have a color point 50 on the 1931 CIE Chromaticity Diagram that is determined by (1) the color point of the light emitted by the blue LED (which is a function of the peak wavelength of the blue LED and the shape of the spectral distribution of the blue LED), (2) the color point of the light emitted by the YAG:Ce phosphor, and (3) the relative intensities of the “pass-through” light emitted by the blue LED and the light emitted by the YAG:Ce phosphor (which will be a function of, among other things, the thickness of the luminophoric medium, the phosphor loading thereof and the sizes of the phosphor particles).

In FIG. 4, two tie lines 54, 54′ are shown. Tie line 54 connects the color point for a blue LED having a peak wavelength of 465 nm to the color point for a YAG:Ce phosphor, while tie line 54′ connects the color point for a blue LED having a peak wavelength of 452 nm to the color point for the YAG:Ce phosphor. Thus, as can be seen in FIG. 4, the shorter peak wavelength of the second blue LED shifts the tie line 54′ to the right of tie line 54 on the 1931 CIE Chromaticity Diagram. The use of shorter wavelength blue LEDs may have several potential advantages including, for example, higher luminous efficiency, improved hot/cold brightness ratio, standardized manufacturing and/or improved inventory control. Unfortunately, however, when shorter wavelength blue LEDs are used it may not be possible to tune the blue-shifted-yellow solid state emitter to emit light in many, or even any, of the sub bins of the x-bin 22 and/or the y-bin 24.

As is also shown in FIG. 4, the above-described effect that the use of a short peak wavelength blue LED may have on the color point of the blue-shifted-yellow solid state emitter may be offset by adding a luminescent material to the luminophoric medium that, when excited by light from the blue LED, emits light having a dominant wavelength in the green color range (i.e., a green luminescent material is added to the luminophoric medium). In particular, as shown by arrow 60 in FIG. 4, the effect of the addition the green luminescent material is to move the color point for the combined light output of the blue-shifted-yellow solid state emitter to the left on the 1931 CIE Chromaticity diagram. Thus, the addition of the green luminescent material may allow the blue-shifted-yellow solid state emitter to emit light in the x-bin 22 and/or the y-bin 24 while using shorter wavelength blue LEDs.

As is further shown by the arrow 62 in FIG. 4, by adding a red luminescent material to the luminophoric medium, it is possible to move color point for the combined light output of the blue-shifted-yellow solid state emitter to the right on the 1931 CIE Chromaticity Diagram. Likewise by adding a yellow luminescent material to the luminophoric medium, it is possible to move color point for the combined light output of the blue-shifted-yellow solid state emitter upward and to the right on the 1931 CIE Chromaticity Diagram. Finally, by allowing relatively more blue light from the blue LED to pass through the luminophoric medium (or by providing blue LEDs which do not have a luminophoric medium) it is possible to move color point for the combined light output of the blue-shifted-yellow solid state emitter downward and to the left on the 1931 CIE Chromaticity Diagram. Thus, by controlling these variables, the color point of the blue-shifted-yellow solid state emitter may be adjusted to fall within any of the sub-regions of the x-bin 22 and/or the y-bin 24 of the blue-shifted-yellow region 20. Thus, pursuant to embodiments of the present invention, blue-shifted-yellow solid state emitters may be provided that use shorter wavelength blue LEDs but which have color points in the blue-shifted-yellow region 20 by, for example, including green luminescent materials in the luminophoric medium. It should be noted that the arrows 60, 62 in FIG. 4 are slightly exaggerated for illustrative purposes, and that that direction that the color point will move may not be quite as differentiated as suggested in FIG. 4.

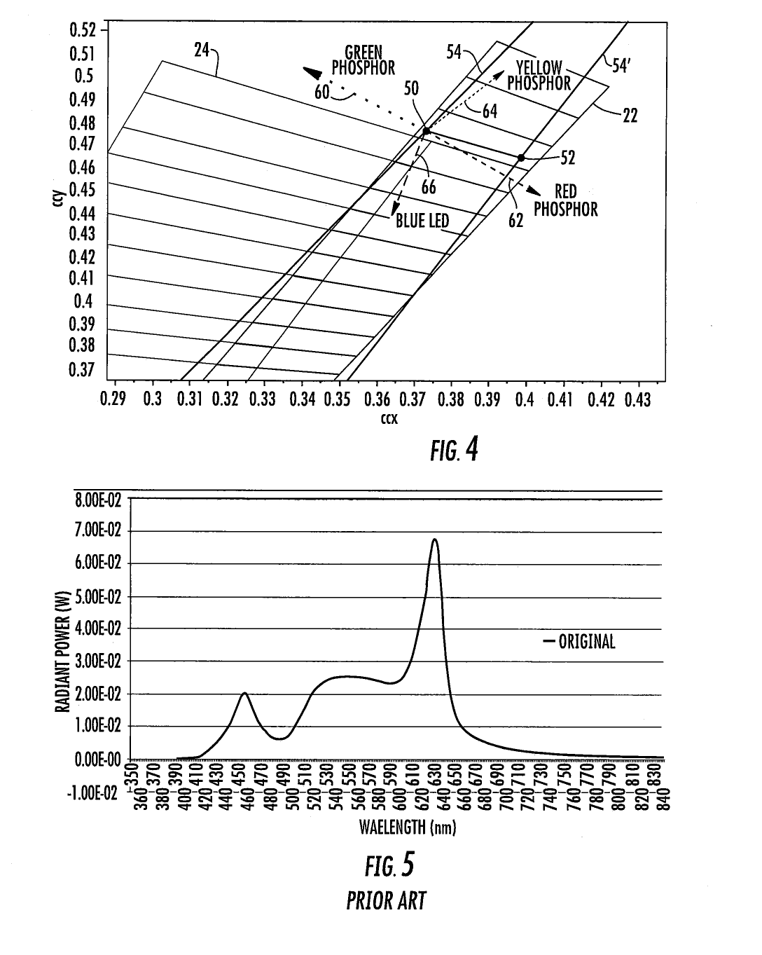

FIG. 5 is a graph of the radiometric spectrum for a light emitting device that includes a conventional blue-shifted-yellow solid state emitter that has an associated luminophoric medium that includes a yellow YAG:Ce phosphor and a red solid state emitter. As shown in FIG. 5, the emission spectrum for the conventional blue-shifted-yellow solid state emitter includes a trough (i.e., a region where emissions are low) between the peak at about 460 nm representing the blue emission of the blue LED and the peak at about 560 nm representing the yellow emission of the YAG:Ce phosphor. The low contribution of radiant flux in this trough generally reduces the CRI for the device. If the blue emission peak corresponding to the “pass-through” blue light emitted by the blue LED is moved to the left, as will happen when a shorter wavelength blue LED is used, the width and depth of the trough are increased, which will generally be expected to correspond to an additional reduction in the CRI for the device. Thus, while the use of the shorter wavelength blue LED may increase the luminous efficiency of the device (as shorter wavelength blue LEDs tend to, on average, have higher luminous efficiency values than longer wavelength blue LEDs), the use of such LEDs may also tend to degrade the color rendering performance of the device.

As discussed above, pursuant to embodiments of the present invention, blue-shifted-yellow solid state emitters are provided in which green luminescent materials may be included in the luminophoric medium. As the green and yellow luminescent materials have significantly overlapping emission spectrums, when the green luminescent material is added to the luminophoric medium, the amount of yellow luminescent material (YAG:Ce) included in the luminophoric medium may be decreased in order to target a specific sub-bin in the blue-shifted-yellow region 2Q. However, as the green peak is to the left of the yellow peak, the general substitution of green luminescent material for yellow luminescent material may result in an increase in the CRI of the device, as the green luminescent material may reduce the size of the above-described trough between the blue and yellow peaks in the emission spectrum. Thus, the use of the green luminescent material may both help hit a desired color point on the 1931 CIE Chromaticity Diagram and may also improve the CRI of the device.

Unfortunately, in some cases, the use of the green luminescent material may not, standing alone, be sufficient to achieve a desired target CRI value such as, for example, a CRI exceeding 90 when shorter wavelength blue LEDs are used. This is particularly true in situations where very short peak wavelength blue LEDs are used (e.g., 430-445 nm). Thus, in some embodiments, a red luminescent material may additionally be added to the luminophoric medium. As discussed above with reference to FIG. 4, the red luminescent materials will move the color point for the blue-shifted-yellow solid state emitter to the right on the 1931 CIE Chromaticity diagram, and hence it may be necessary to increase the amount of green luminescent materials (and perhaps decrease the amount of yellow luminescent material). The additional green and red luminescent materials tend to help fill in the emission spectrum and improve the CRI of the device.

In some embodiments, the red luminescent materials that are added to the luminophoric medium may have a different dominant wavelength than the red solid state emitter. For example, in some embodiments, the red solid state emitter may have a dominant wavelength between 605 and 625 nm while the red luminescent materials included in the luminophoric medium may have a dominant wavelength of between 625 and 635 nm. In some embodiments, the red solid state emitter may have a dominant wavelength between 610 and 620 nm while the red luminescent materials included in the luminophoric medium may have a dominant wavelength of between 627 and 633 nm. As a result of these different emission peaks, the emission spectrum for the device is further smoothed out, and this may increase the CRI of the device. In some embodiments, narrow spectrum red luminescent materials may be used that have a FWHM width of less than 50 nm or, in some embodiments, of less than 30 nm or even less than 20 nm. This may help minimize the amount of spectral energy that is at the edge of or outside the visible range. For example, red light emitting quantum dots may be used as the red luminescent material in some embodiments. The red luminescent material may be used to adjust the location of the color point of the light emitting device in, for example, cases where the amount of green luminescent materials moves the color point to far up and/or to the left on the 1931 CIE Chromaticity Diagram.

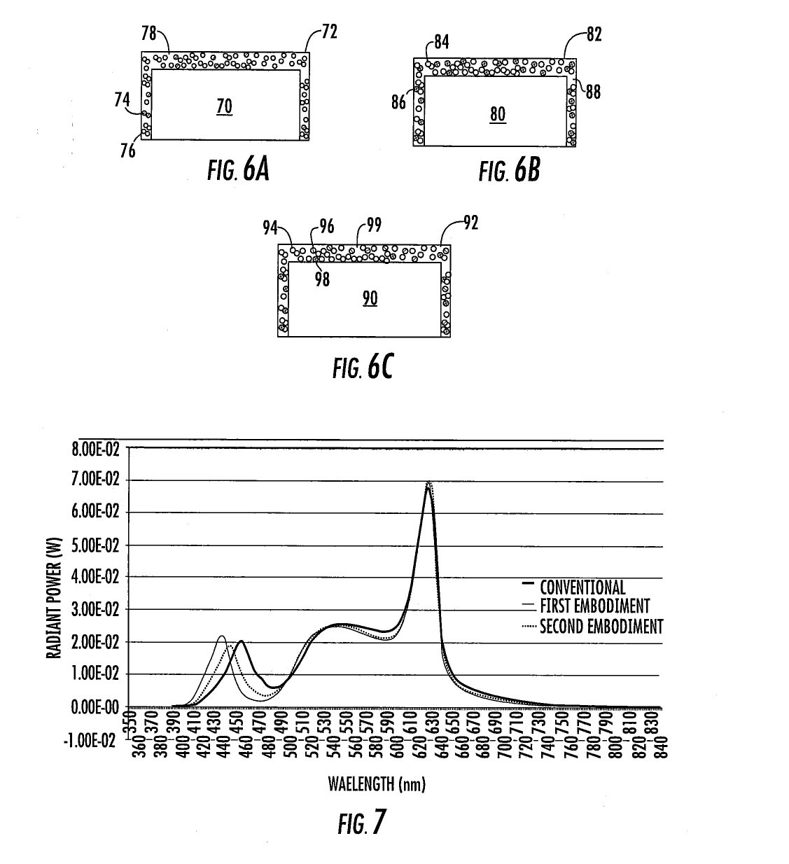

FIGS. 6A-6C are schematic cross-sectional diagrams of blue-shifted-yellow solid state emitters according to certain embodiments of the present invention. As shown in FIG. 6A, in some embodiments, a blue-shifted-yellow solid state emitter includes a blue LED 70 and a luminophoric medium 72 that includes green luminescent materials 74 and yellow luminescent materials 76 that are dispersed in a binder material 78 such as a silicone or epoxy resin. As shown in FIG. 6B, in other embodiments, a blue-shifted-yellow solid state emitter includes a blue LED 80 and a luminophoric medium 82 that includes green luminescent materials 84 and red luminescent materials 86 that are dispersed in a binder material 88. As shown in FIG. 6C, in still other embodiments, a blue-shifted-yellow solid state emitter includes a blue LED 90 and a luminophoric medium 92 that includes green luminescent materials 94, yellow luminescent materials 96 and red luminescent materials 98 that are dispersed in a binder material 99. While in FIGS. 6A-6C show the various luminophoric materials intermixed within a single layer, it will be appreciated that the luminophoric materials may be contained in separate layers in other embodiments, and that these separate layers may be directly adjacent each other and/or may be separated from each other. It will also be appreciated that other luminescent materials may be added. For example, luminescent materials that, when excited, emit light in the cyan color range (e.g., between 486 and 499 nm) may also be included in any of the above-described luminophoric mediums.

Pursuant to some embodiments, light emitting devices were fabricated that include one or more blue-shifted-yellow solid state emitters that are combined with one or more red solid state emitters in the form of an aluminum indium gallium phosphide based LEDs having a dominant wavelength of, for example, about 610-615 nm. The green phosphors were LuAG:Ce phosphors, the yellow phosphors were YAG:Ce phosphors, and the red phosphors were (Ca_{1-x-y}SrₓEu²⁺_{y})SiN₂ phosphors. The goal was to provide light emitting devices having luminous efficiencies of at least 145 lumens/watt for the blue-shifted-yellow solid state emitter, a luminous efficiency of at least 115 lumens/watt for the device as a whole, and a CRI of at least 90.

In some embodiments, the blue-shifted-yellow solid state emitters included an associated luminophoric medium that comprises a green luminescent material and a red luminescent material. In these embodiments, the green luminescent material may comprise, for example, by weight, at least 90% of the luminescent materials included in the luminophoric medium, and the red luminescent material may comprise, by weight, less than 10% of the luminescent materials included in the luminophoric medium. These blue-shifted-yellow solid state emitters may, for example, use blue LEDs having peak wavelengths of less than 450 nm, and may target the y-bins 24 of the blue-shifted-yellow region 20. Example embodiments achieved a luminous efficiency value of 155 lumens per watt and a CRI value of 92.4 at a correlated color temperature of 4000K and a luminous efficiency value of 146 lumens per watt and a CRI value of 91.7 at a correlated color temperature of 5000K.

In other embodiments, the blue-shifted-yellow solid state emitters included an associated luminophoric medium that comprises a green luminescent material, a yellow luminescent material and a red luminescent material. In these embodiments, the green luminescent material may comprise, for example, by weight, between 20% and 50% of the luminescent materials included in the luminophoric medium, the yellow luminescent material may comprise, for example, by weight, between 50% and 70% of the luminescent materials included in the luminophoric medium, and the red luminescent material may comprise, for example, by weight, less than 5% of the luminescent materials included in the luminophoric medium. These blue-shifted-yellow solid state emitters may, for example, use blue LEDs having peak wavelengths of less than 450 nm, and may target the x-bins 22 of the blue-shifted-yellow region 20. Example embodiments achieved a luminous efficiency value of 150 lumens per watt and a CRI value of 92.4 at a correlated color temperature of 3000K and a luminous efficiency value of 154 lumens per watt and a CRI value of 92.8 at a correlated color temperature of 3500K.

In still other embodiments, the blue-shifted-yellow solid state emitters included an associated luminophoric medium that comprises a green luminescent material and a yellow luminescent material. In these embodiments, the green luminescent material may comprise, for example, by weight, between 15% and 40% of the luminescent materials included in the luminophoric medium, and the yellow luminescent material may comprise, for example, by weight, between 60% and 85% of the luminescent materials included in the luminophoric medium. These blue-shifted-yellow solid state emitters may, for example, use blue LEDs having peak wavelengths of less than 450 nm, and may target the x-bins 22 of the blue-shifted-yellow region 20. Example embodiments achieved a luminous efficiency value of 149 lumens per watt and a CRI value of 91.6 at a correlated color temperature of 3000K and a luminous efficiency value of 152 lumens per watt and a CRI value of 91.2 at a correlated color temperature of 3500K.

In still further embodiments, the blue-shifted-yellow solid state emitters included an associated luminophoric medium that comprises a green luminescent material and a yellow luminescent material. In these embodiments, the green luminescent material may comprise, for example, by weight, between 60% and 85% of the luminescent materials included in the luminophoric medium, and the yellow luminescent material may comprise, for example, by weight, between 15% and 40% of the luminescent materials included in the luminophoric medium. These blue-shifted-yellow solid state emitters may, for example, use blue LEDs having peak wavelengths of less than 450 nm, and may target the y-bins 24 of the blue-shifted-yellow region 20. Example embodiments achieved a luminous efficiency value of 148 lumens per watt and a CRI value of 90.5 at a correlated color temperature of 4000K and a luminous efficiency value of 141 lumens per watt and a CRI value of 88.0 at a correlated color temperature of 5000K.

As discussed above, in some embodiments the red luminescent material may comprise a small percentage of the total luminescent materials that are included in the luminophoric medium. For example, in some embodiments, the red luminescent materials may comprise less than 10% by weight of the luminescent materials included in the luminophoric medium. In other embodiments, the red luminescent materials may comprise less than 5% by weight of the luminescent materials included in the luminophoric medium.

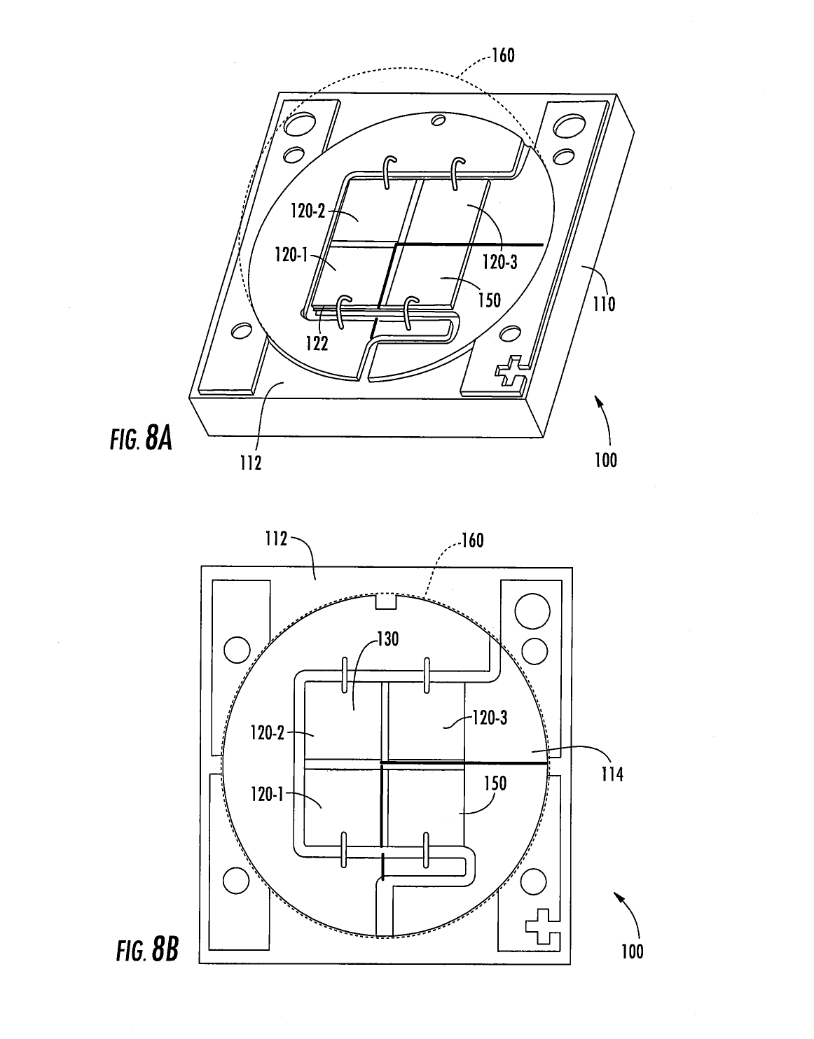

FIG. 7 is a graph illustrating the emission spectra of two example light emitting devices according to embodiments of the present invention as compared to the emission spectrum of a light emitting device that includes the conventional blue-shifted-yellow solid state emitter that was depicted in FIG. 5. As shown in FIG. 7, each device has essentially the same peak in its emission spectrum at about 630 nm, which corresponds to the light emitted by the red solid state emitter. However, the peak wavelengths of the blue LEDs are substantially different, with the blue LEDs used in the light emitting devices according to embodiments of the present invention having significantly shorter wavelengths. This tends to increase the width of the trough in the emission spectrum in the cyan color range. One of the shorter wavelength blue LEDs exhibits increased spectral output as compared to the longer wavelength blue LED used in the conventional device. It would generally be expected, on average, that the shorter wavelength blue LEDs will exhibit such higher spectral output. As is also shown in FIG. 7, the addition of the green luminescent materials also helps fill in the trough in the cyan region of the emission spectrum, which may improve the CRI of the device. The red luminescent materials included in one of the embodiments also help fill in a small trough that exists between the yellow and red peaks in the emission spectrum.

One side benefit that is seen in light emitting devices according to embodiments of the present invention that include red luminescent materials in the luminophoric medium is improved R9 color rendering performance. As discussed above, the R9 color rendering parameter measures the ability of a light source to reproduce a saturated red color, which may be important in many applications. The addition of the red phosphor in the luminophoric medium can improve the CRI R9 performance of the device. For example, Table 1 below illustrates the performance characteristics, including CRI R9 performance, of a light emitting device that includes a conventional blue-shifted-yellow solid state emitter (labeled “Conventional BSY SSE+Red SSE”) in Table 1) and a light emitting device that includes a blue-shifted-yellow solid state emitter according to embodiments of the present invention (labeled “BSY SSE with Green, Yellow and Red Phosphors and Red SSE”) in Table 1). As shown in Table 1, the two light emitting devices have comparable correlated color temperatures. The conventional device has higher CRI performance, but has lower luminous efficiency and lower CRI R9 performance. The shorter wavelength blue LED of the light emitting device according to embodiments of the present invention (444 nm versus 458 nm for the conventional light emitting device) contributes to the higher luminous efficiency values while the red phosphor included in the luminophoric medium contributes to the improved CRI R9 performance.

TABLE 1

| | Blue Peak | | CCT | | |
|---|---|---|---|---|---|
| Light Emitting Device | (nm) | LPW | (K) | CRI | R9 |
| Conventional BSY SSE + | 458 | 100.3 | 3039 | 94.5 | 91.9 |
| Red SSE | | | | | |
| BSY SSE with Green, | 444 | 104.6 | 3053 | 90.1 | 96.5 |
| Yellow and Red | | | | | |
| Phosphors + Red SSE | | | | | |

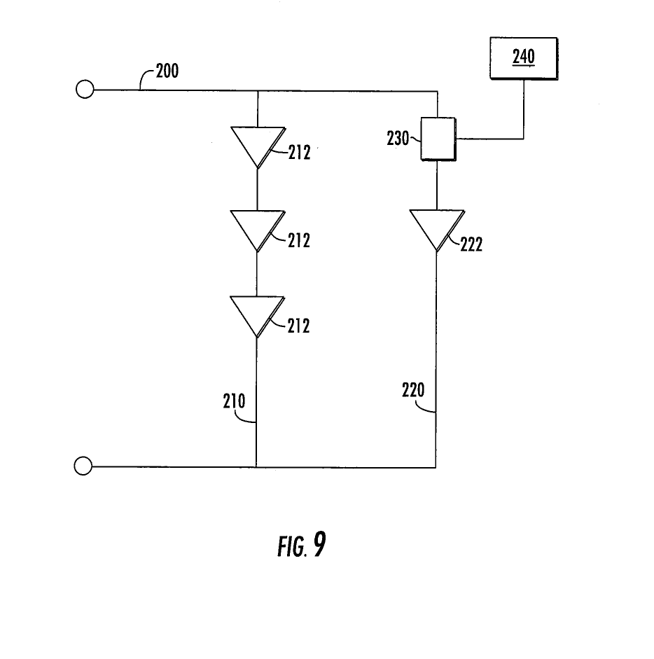

FIGS. 8A and 8B are a top perspective view and a top view, respectively, of a light emitting device 100 according to certain embodiments of the present invention.

As shown in FIGS. 8A-8B, the light emitting device includes four solid state emitters 120-1, 120-2, 120-3 and 150 that are mounted on a submount 110. The submount 110 can be formed of many different materials such as, for example, aluminum oxide, aluminum nitride, organic insulators, a printed circuit board (PCB), sapphire or silicon.

An optical element or lens 160 is formed on the top surface 112 of the submount 110 to enclose the solid state emitters 120-1, 120-2, 120-3 and 150. The solid state emitters 120-1, 120-2, 120-3 may comprise blue-shifted-yellow solid state emitters, while the solid state emitter 150 may be a red solid state emitter. The lens 160 may provide environmental and/or mechanical protection to the solid state emitters 120-1, 120-2, 120-3 and 150. The lens 160 can be molded using different molding techniques such as those described in U.S. patent application Ser. No. 11/982,275 entitled Light Emitting Diode Package and Method for Fabricating Same. The lens 160 can be many different shapes such as, for example, hemispheric. Many different materials can be used for the lens 160 such as silicones, plastics, epoxies or glass. The lens 160 can also be textured to improve light extraction.

The blue-shifted-yellow solid state emitters 120-1, 120-2, 120-3 may each comprise a blue LED 122 that includes an associated luminophoric medium 130. Each blue LED 122 may comprise, for example, a gallium nitride based blue LED that, when excited, emits blue light having a peak wavelength between 430 nm and 480 nm. In some embodiments, the blue LEDs 122 may each, when excited, emit blue light having a peak wavelength between 430 nm and 465 nm. In other embodiments, the blue LEDs 122 may each, when excited, emit blue light having a peak wavelength between 440 nm and 455 nm. Some embodiments of the light emitting devices disclosed herein may use lower wavelength blue LEDs 122 such as LEDs that emit blue light having a peak wavelength of 450 nm or less. The use of such LEDs may, in some cases, provide light emitting devices that exhibit improved luminous efficiency and/or color rendering properties, and may also provide manufacturing and inventory control advantages.

The LEDs 122 can have many different semiconductor layers arranged in different ways. LED structures and their fabrication and operation are generally known in the art and hence are only briefly discussed herein. The layers of the LEDs 122 can be fabricated using known processes such as, for example, metal organic chemical vapor deposition (MOCVD). The layers of the LEDs 122 may include at least one active layer/region sandwiched between first and second oppositely doped epitaxial layers all of which are formed successively on a growth substrate. Typically, many LEDs are grown on a growth substrate such as, for example, a sapphire, silicon carbide, aluminum nitride, or gallium nitride substrate to provide a grown semiconductor wafer, and this wafer may then be singulated into individual LED dies. The growth substrate can remain as part of the final singulated LED or, alternatively, the growth substrate can be fully or partially removed. In embodiments where the growth substrate remains, it can be shaped and/or textured to enhance light extraction.

It is also understood that additional layers and elements can also be included in the LEDs 122, including but not limited to buffer, nucleation, contact and current spreading layers as well as light extraction layers and elements. It is also understood that the oppositely doped layers can comprise multiple layers and sub-layers, as well as super lattice structures and interlayers. The active region can comprise, for example, a single quantum well (SQW), multiple quantum well (MQW), double heterostructure and/or super lattice structure. The active region and doped layers may be fabricated from different material systems, including, for example, Group-III nitride based material systems such as gallium nitride, aluminum gallium nitride, indium gallium nitride and/or aluminum indium gallium nitride.

The luminophoric medium 130 may, for example, be conformally coated on at least upper surfaces of the blue-shifted-yellow solid state emitters 120-1, 120-2, 120-3 (which are collectively referred to as the blue-shifted-yellow solid state emitters 120). In some embodiments, the luminophoric medium 130 may be conformally coated on the blue-shifted-yellow solid state emitters 120-1, 120-2, 120-3 and on the portions of the submount 110 between the blue-shifted-yellow solid state emitters 120-1, 120-2, 120-3. In some embodiments, the luminophoric medium 130 may also be conformally coated on the red solid state emitter 150 and on the portions of the submount 110 between the blue-shifted-yellow solid state emitters 120-1, 120-2, 120-3 and the red solid state emitter 150. In such embodiments, the luminescent materials in the luminophoric medium may generally not be excited by light in the red color range. The luminophoric medium 130 may be coated on the LEDs 120 using many different methods, with suitable methods being described in U.S. patent application Ser. Nos. 11/656,759 and 11/899,790, both entitled Wafer Level Phosphor Coating Method and Devices Fabricated Utilizing Method. In other embodiments, the luminophoric medium 130 may be spray coated on the LEDs 120 using, for example, the techniques disclosed in U.S. patent application Ser. No. 12/717,048 entitled Systems and Methods for Application of Optical Materials to Optical Elements, the entire content of which is incorporated herein by reference. Alternatively the luminophoric medium 130 may be coated on the LEDs 120 using other methods such an electrophoretic deposition (EPD), with a suitable EPD method described in U.S. patent application Ser. No. 11/473,089 entitled Close Loop Electrophoretic Deposition of Semiconductor Devices.

In still other embodiments, the luminophoric medium 130 may be coated on the LEDs 120 using stencil printing techniques. In this approach, multiple LEDs 120 may be arranged on a mounting substrate and a stencil is then positioned on the substrate that has openings that align with the LEDs, with the holes being slightly larger than the LEDs. A luminophoric medium 130 is then deposited in the stencil openings in a liquid state to cover the LEDs 120, and the liquid is then cured by, for example, heat or light and the stencil is removed to leave a solid luminophoric medium 130 on the LEDs 120. In yet further embodiments, droplet deposition systems similar to ink jet printing apparatus may be used to spray a liquid luminophoric medium 130 onto an LED 120. In this technique, droplets of the liquid luminophoric medium are sprayed from a nozzle on the print head in response to pressure generated in the print head by a thermal bubble and/or by piezoelectric crystal vibrations.

It will be appreciated, however, that the luminophoric medium 130 may be provided in different locations in other embodiments. For example, the luminophoric medium 130 may be coated on the lens 160, may be mounted between the solid state emitters 120-1, 120-2, 120-3 and 150 and the lens 160 so as to not be in direct contact with the solid state emitters 120-1, 120-2, 120-3 and 150. It will also be appreciated that the luminophoric medium 130 need not be conformally coated on a surface. For example, in some embodiments, the luminophoric medium 130 may partially or completely fill an optical cavity that includes one or more of the solid state emitters 120-1, 120-2, 120-3 and 150.

The luminophoric medium 130 may include a binder material, and may have different concentrations or loading of luminescent materials such as phosphors in the binder. The binder may comprise, for example, a transparent silicone or an epoxy binder, or other matrix material. A typical concentration of luminescent materials in the binder may be in range of 30-70% by weight, although other concentrations may be used. The luminophoric medium 130 can comprise a single layer or multiple layers of the same or different concentrations or types of luminescent materials. If multiple layers are provided, they may comprise different types binder materials. One or more of the layers can be provided without luminescent materials. For example, a first coat of clear silicone can be deposited followed by phosphor loaded layers.

The luminophoric medium 130 may further include any of a number of well-known additives, e.g., diffusers, scatterers, tints, etc. It will also be appreciated that the luminescent materials can be placed in and/or on an encapsulant and/or optic of the LED, such as silicone, epoxy or glass as opposed to coated on the LED. The luminescent materials can be mixed together in the matrix and/or positioned separately (in a remote phosphor configuration) on the optic and/or in discrete layers on the LED.

The red solid state emitter 150 may comprise, for example, a red LED that emits red light having a dominant wavelength between 600 and 660 nm. In some embodiments, the red LED may comprise an aluminum indium gallium phosphide based LED. The red LED may emit nearly saturated red light. In some embodiments, the red LED may emit light having a dominant wavelength in the range of from about 610 nm to about 620 nm.

In other embodiments, the red solid state emitter 150 may comprise, for example, a blue-shifted-red LED or some other phosphor converted LED (e.g., an ultraviolet LED) that comprises, for example, an LED that emits light in a first color range at least some of which excites luminescent materials in a luminophoric medium that emit light in the red color range in response thereto. The use of blue-shifted-red LEDs may have certain advantages, including a broader emission spectrum in the red color range that may provide enhanced color rendering performance, and more consistent performance between the blue-shifted-yellow and blue-shifted-red LEDs as a function of operating temperature and/or age of the devices, which may allow the use of more simplified control circuitry. However, at least in some cases, the luminous output and/or the efficiency of blue-shifted-red LEDs may be less than that of the above-described red aluminum indium gallium phosphide based LEDs.

The top surface 112 of the submount 110 may have patterned conductive features that can include one or more die attach pads 114. The die attach pad(s) 114 may comprise a metal or other conductive material such as, for example, copper. The solid state emitters 120-1, 120-2, 120-3 and 150 may be mounted on the respective die attach pads 114. In the depicted embodiment, the blue-shifted-yellow solid state emitters 120-1, 120-2, 120-3 are mounted in a so-called “flip-chip” configuration in which the uppermost layer(s) of each LED 122 that is opposite the growth substrate—which typically include at least a metal contact that connects to a p-type layer of the LED 122 if the LEDs 122 are gallium nitride based LEDs—is mounted to directly contact its respective die attach pad 114. In this flip chip configuration, the LED 122 and/or the die attach metallization may include one or more reflective layers and light generated by the LED 122 is output through the substrate and side surfaces of the LED 122. It will also be appreciated that the substrate may be partially or completely removed. Contact structures are provided for electrically connecting a voltage source to the respective n-type and p-type sides of the LEDs 120. Contact arrangements for powering LEDs mounted in both conventional and flip-chip configurations are well known in the art and need not be discussed further here.

It has been discovered that when a blue-shifted-yellow solid state emitter includes a luminophoric medium having a silicone binder and a short wavelength blue LED, the blue photon energy may eventually lead to cracks in the silicone if the luminophoric medium is coated onto the blue LED close to the active area of the LED. Accordingly, in some embodiments, the blue LEDs that are included in the blue-shifted-yellow solid state emitters may be mounted on a submount in flip-chip configuration, and the luminophoric medium may be coated onto or otherwise deposited on the substrate of the LED so that the luminophoric medium is sufficiently spaced-apart from the active area of the LED. If cracks appear in the silicone, they may lead to pathways for blue light to pass through the luminophoric medium without exciting phosphor particles which can degrade the color of the overall output of the light emitting device.

As shown in FIG. 9, in some embodiments of the present invention, a set of parallel solid state light emitter strings 21Q, 220 (i.e., two or more strings of solid state light emitters arranged in parallel with each other) is arranged in series with a power line 200, such that current is supplied through the power line 200 to each of the respective strings 210, 220 of solid state light emitters. The first string 210 in the depicted embodiment includes three solid state emitters 212, each of which comprises a blue-shifted-yellow solid state emitter according to embodiments of the present invention. The second string 220 includes a single red solid state emitter 222. The expression “string”, as used herein, means that at least one solid state light emitter is provided and that the solid state emitters in the string are electrically connected in series. In some embodiments, the blue-shifted-yellow solid state emitters 212 are in the first string 210 and the red solid state emitter(s) 222 are in the second string 220. In other embodiments, both blue-shifted-yellow solid state emitters 212 and red solid state emitters 222 may be in the second string 220. The relative quantities of solid state light emitters in the respective strings 210, 220 may differ from one string to the next. More than two strings may be provided.

In some embodiments, the intensity of the light emitted by the red solid state emitters 222 relative to the blue-shifted-yellow solid state emitters 212 can be increased, when necessary, in order to compensate for any reduction of the intensity of the light generated by the red solid state emitters 222. Thus, for instance, by increasing the current supplied to one or more strings 220 that have red solid state emitters 222 and/or by decreasing the current supplied to the string(s) 210 having blue-shifted-yellow solid state emitters 212, the ccx, ccy coordinates of the mixture of light emitted from the lighting device can be appropriately adjusted.

As is also shown in FIG. 9, in some embodiments, one or more current adjusters 230 may be directly or switchably electrically connected to one or more of respective strings of solid state emitters. These current adjusters 230 can adjust the current supplied to one or more of the respective strings of solid state light emitters. In some embodiments, the current adjuster 230 is automatically adjusted to maintain the mixture of light within a four-step MacAdam ellipse of at least one point on the blackbody locus on a 1931 CIE Chromaticity Diagram.

In some embodiments, the light emitting device may further include one or more thermistors 240 which detect temperature. The light emitting device may be configured so that as the temperature changes, one or more current adjusters 230, switches or the like may automatically interrupt and/or adjust current passing through one or more respective strings in order to compensate for such temperature change. In some embodiments, the red solid state emitters may get dimmer relative to the blue-shifted-yellow solid state emitters as the temperature increases. The thermistors 240 and associated circuitry may compensate for fluctuations in intensity caused by such temperature variation. While the current adjuster 230 and the thermistor 240 are shown as being configured to control and adjust the current on the second string 220 in FIG. 9, it will be appreciated that any or all strings in the light emitting device may include such current adjustment.

The light emitting devices according to some embodiments of the present invention may emit light that has, for example, a CRI value of at least 90 and may define a color point that is within a four-step MacAdam ellipse of at least one point on the black-body locus 16 on a 1931 CIE Chromaticity Diagram, and may have a color temperature in the range of 2000-5500K, where the color temperature of the light emitted by the light emitting device is defined as the color temperature of the point on the black-body locus that is closest to the color point of the light emitted by the light emitting device. In some embodiments, the light emitting devices may be designed to emit warm white light that has a correlated color temperature of between about 2500K and about 4500K. In some embodiments, the correlated color temperature is between about 2500K and about 3300K. The light emitting devices may achieve very high luminous efficiency. For example, in some embodiments, the light emitting devices may achieve luminous efficiency of at least 140 lumens/watt. In other embodiments, the light emitting devices may achieve luminous efficiency of at least 145 lumens/watt, and in still other embodiments, may achieve luminous efficiency of at least 150 lumens/watt. These luminous efficiency values may, in some cases, exceed the luminous efficiency values that are consistently achievable with conventional light emitting devices that include blue-shifted-yellow solid state emitters that use a single luminescent material.

While FIGS. 8A and 8B illustrate one example of a packaged light emitting device according to embodiments of the present invention, it will be appreciated that the light emitting devices according to embodiments of the present invention may come in many different forms. In some embodiments, the light emitting devices may comprise one or more blue-shifted-yellow solid state emitters and one or more red solid state emitters, where each solid state emitter is a separate component. The light emitted from these separate components may then be mixed at the light fixture level using, for example, a diffuser or other optics. In other embodiments, the light emitting device may include a plurality of blue-shifted-yellow solid state emitters that are packaged together as a first component and a plurality of red solid state emitters that are packaged together as a separate second component. The light emitted from these two separate components may then be mixed at the light fixture level. In still other embodiments, a component may be provided that includes at least one blue-shifted-yellow solid state emitter and at least one red solid state emitter which are packaged and useable together. The above-described components may be integrated into a wide variety of other devices such as, for example, flashlights, electronic products, automobiles, etc. In other embodiments, the light emitting devices may be directly incorporated into, for example, light fixtures such as, for example, ceiling mounted light fixtures such as can lights (60 or 65 Watt downward pointing flood lights) and solid state ceiling fixtures for office buildings that replace fluorescent lighting. Numerous other arrangements are possible. The light emitting devices according to embodiments of the present invention may be particularly well-suited for applications where the light from the solid state emitters passes through a diffuser and/or is reflected and given an opportunity to mix so that the light from the blue-shifted-yellow and red solid state emitters may sufficiently mix to appear to a human observer as if the light was emitted from a single, white light source.

It will likewise be appreciated that numerous different packaging techniques may be used. For example, while the embodiment of FIGS. 8A-8B use die attach pads, in other embodiments the LEDs may be mounted directly to an alumina submount (or submount formed of another material) using a silicone or epoxy die attach without any metal traces. The LEDs may or may not be mounted in flip-chip form, and may include, for example, zero, one or two wire bonds per LED. Thus, it will be appreciated that FIGS. 8A-8B are merely provided to illustrate one example packaging technique for the light emitting devices according to embodiments of the present invention and it will likewise be appreciated that nay appropriate packaging technique may be used.

It will also be appreciated that pursuant to embodiments of the present invention light emitting devices are provided that include an LED that, when excited, emits visible light, and an associated luminophoric medium that includes at least a first luminescent material that, when excited by light from the LED, emits light having a dominant wavelength in the red color range. The light emitted by the combination of the LED and all of the luminescent materials in the associated luminophoric medium has a color point that is both above the black body locus on the 1931 CIE Chromaticity Diagram and within a 10-step MacAdam ellipse of the black body locus. While in some embodiments, this light emitting device may be a blue-shifted-yellow solid state emitter, the present invention is not limited thereto. In other embodiments, the techniques disclosed herein may be used to generate a combined light output that targets other regions of the 1931 CIE Chromaticity diagram. For example, a green light emitting LED could be combined with the luminophoric medium that includes at least a red luminescent material to generate light having a wide variety of different color points that above the black body locus on the 1931 CIE Chromaticity Diagram.

The light emitting devices according to embodiments of the present invention provide a number of advantages over conventional light emitting devices. As discussed above, the light emitting devices may be formed using blue-shifted-yellow solid state emitters that are formed using short wavelength blue LEDs. This may help streamline manufacturing by reducing the number of different peak wavelengths that are targeted during manufacturing runs. As the targeted peak wavelength will affect the growth recipe, reducing the number of target peak wavelengths may simplify manufacturing operations.

The use of shorter wavelength blue LEDs in the blue-shifted-yellow solid state emitters may also provide for increased luminous efficiency as compared to conventional blue-shifted-yellow solid state emitters. Moreover, the color rendering performance of the devices according to embodiments of the present invention may be comparable to, or better than, conventional white light emitting devices that use blue-shifted-yellow solid state emitters, and the R9 color rendering performance may be significantly improved in many cases.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The present invention has been described with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. The singular forms “a”, “an” and “the” are intended to include the plural forms as well, unless the context clearly indicates otherwise. It will be further understood that, when used in this specification, the terms “comprises” and/or “including” and derivatives thereof, specify the presence of stated features, operations, elements, and/or components, but do not preclude the presence or addition of one or more other features, operations, elements, components, and/or groups thereof.

It will be understood that, although the terms first, second, etc. may be used herein to describe various elements, components, regions and/or layers, these elements, components, regions and/or layers should not be limited by these terms. These terms are only used to distinguish one element, component, region or layer from another element, component, region or layer. Thus, a first element, component, region or layer discussed below could be termed a second element, component, region or layer without departing from the teachings of the present invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure.

The expression “light emitting device,” as used herein, is not limited, except that it be a device that is capable of emitting light.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A light emitting device, comprising:
a first group of at least one blue-shifted-yellow solid state emitter, each blue-shifted-yellow solid state emitter comprising a blue light emitting diode (“LED”) that, when excited, emits light having a peak wavelength in the blue color range, and an associated luminophoric medium that includes at least a first luminescent material that, when excited by light from the blue LED, emits light having a dominant wavelength in the green color range, a second luminescent material that, when excited by light from the blue LED, emits lights having a dominant wavelength in the yellow color range, and a third luminescent material that, when excited by light from the blue LED, emits light having a dominant wavelength in the red color range, each blue-shifted-yellow solid state emitter emitting light having a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295); and
a second group of at least one red solid state emitter that emits light having a dominant wavelength in the red color range.

2. The light emitting device of claim 1, wherein the blue LED emits light having a peak wavelength of less than 455 nanometers.

3. The light emitting device of claim 1, wherein the dominant wavelength of the third luminescent material is greater than the dominant wavelength of the at least one red solid state emitter.

4. The light emitting device of claim 1, wherein the third luminescent material has a full-width-half-maximum width that is less than the full-width-half-maximum width of the at least one red solid state emitter.

5. The light emitting device of claim 1, wherein the color temperature of the light emitted by the combination of the first group of at least one blue-shifted-yellow solid state emitter and the first group of at least one red solid state emitter is less than 5500K.

6. The light emitting device of claim 1, wherein a weight of the third luminescent material comprises less than ten percent of a sum of weights of the first, second and third luminescent materials.

7. The light emitting device of claim 1, wherein the light emitted by the combination of the first group of at least one blue-shifted-yellow solid state emitter and the second group of at least one red solid state emitter has a color point that is within a 4-step MacAdam ellipse of a black-body locus on the 1931 CIE Chromaticity Diagram.

8. The light emitting device of claim 2, wherein the luminophoric medium comprises a silicone binder and is coated directly onto the blue LED, and wherein the blue LED is mounted in flip-chip configuration on a submount.

9. The light emitting device of claim 1, wherein each blue-shifted-yellow solid state emitter emits light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361).

10. The light emitting device of claim 1, wherein a weight of the first luminescent material is between 20 and 50 percent of a sum of the weights of the first, second and third luminescent materials, a weight of the second luminescent material is between 50 and 70 percent of the sum of weights of the first, second and third luminescent materials, and a weight of the third luminescent material is less than 5 percent of the sum of the weights of the first, second and third luminescent materials.

11. The light emitting device of claim 1, wherein the blue LED emits light having a peak wavelength of less than 455 nanometers, the dominant wavelength of the third luminescent material is greater than the dominant wavelength of the at least one red solid state emitter, the color temperature of the light emitted by the combination of the first group of at least one blue-shifted-yellow solid state emitter and the first group of at least one red solid state emitter is less than 5500K, each blue-shifted-yellow solid state emitter emits light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361), and a weight of the first luminescent material is between 20 and 50 percent of a sum of weights of the first, second and third luminescent materials, a weight of the second luminescent material is between 50 and 70 percent of the sum of the weights of the first, second and third luminescent materials, and a weight of the third luminescent material is less than 5 percent of the sum of the weights of the first, second and third luminescent materials

12. A light emitting device, comprising:
a first group of at least one blue-shifted-yellow solid state emitter, each blue-shifted-yellow solid state emitter comprising a blue light emitting diode (“LED”) that, when excited, emits light having a peak wavelength in the blue color range, and an associated luminophoric medium that includes at least a first luminescent material and a second luminescent material that, when excited by light from the blue LED, emit light having a dominant wavelength in respective first and second color ranges, wherein the first and second color ranges are different color ranges selected from the group of a green color range, a yellow color range and a red color range, each blue-shifted-yellow solid state emitter emitting light having a color point on the 1931 CIE Chromaticity Diagram in a region defined by ccx, ccy coordinates of (0.226, 0.295), (0.295, 0.298), (0.323, 0.360), (0.344, 0.358), (0.422, 0.496), (0.391, 0.517), (0.371, 0.477), (0.506, 0.303), (0.226, 0.295); and
a second group of at least one red solid state emitter that emits light having a dominant wavelength in the red color range,
wherein the light emitted by the combination of the first group of at least one blue-shifted-yellow solid state emitter and the second group of at least one red solid state emitter has a color point that is within a 4-step MacAdam ellipse of a black-body locus on the 1931 CIE Chromaticity Diagram.

13. The light emitting device of claim 12, wherein the blue LED emits light having a peak wavelength of less than 450 nanometers.

14. The light emitting device of claim 12, wherein the first color range is the green color range and the second color range is the yellow color range, and wherein the associated luminophoric medium for each blue-shifted-yellow solid state emitter further includes a third luminescent material that, when excited by light from the blue LED, emits light having a dominant wavelength in the red color range.

15. The light emitting device of claim 12, wherein the first color range is the green color range and the second color range is the red color range.

16. The light emitting device of claim 12, wherein the first color range is the green color range and the second color range is the yellow color range.

17. The light emitting device of claim 12, wherein the color temperature of the light emitted by the combination of the at least one phosphor-converted LED and the at least one red LED is less than 5500K.

18. The light emitting device of claim 15, wherein the second luminescent materials comprise less than ten percent by weight of the luminescent materials included in the luminophoric medium.

19. The light emitting device of claim 16, wherein each blue-shifted-yellow solid state emitter emitting light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361) and an amount of the first luminescent material that is included in the luminophoric medium is less than an amount of the second luminescent material that is included in the luminophoric medium, by weight.

20. The light emitting device of claim 16, wherein each blue-shifted-yellow solid state emitter emitting light having a color point on the 1931 CIE Chromaticity Diagram in a region defined by ccx, ccy coordinates of (0.311, 0.361), (0.344, 0.358), (0.422, 0.496), (0.391, 0.517), (0.311, 0.361) and an amount of the first luminescent material that is included in the luminophoric medium is less than half an amount of the second luminescent material that is included in the luminophoric medium, by weight.

21. The light emitting device of claim 12, wherein the first color range is the green color range, wherein the first luminescent materials comprise at least seventy percent by weight of the total luminescent materials included in the luminophoric medium, and wherein each blue-shifted-yellow solid state emitter emits light having a color point on the 1931 CIE Chromaticity Diagram in a region defined by ccx, ccy coordinates of (0.226, 0.295), (0.295, 0.298), (0.375, 0.472), (0.506, 0.303), (0.226, 0.295).

22. The light emitting device of claim 13, wherein the luminophoric medium includes a silicone binder and is coated directly onto the blue LED, and wherein the blue LED is mounted in flip-chip configuration on a submount.

23. A light emitting device, comprising:
a first group of at least one blue-shifted-yellow solid state emitter, each blue-shifted-yellow solid state emitter comprising a blue light emitting diode (“LED”) that, when excited, emits light having a peak wavelength in the blue color range, and an associated luminophoric medium that includes at least a first luminescent material that, when excited by light from the blue LED, emits light having a dominant wavelength in the green color range and a second luminescent material that, when excited by light from the blue LED, emits lights having a dominant wavelength in the red color range, each blue-shifted-yellow solid state emitter emitting light having a color point on the 1931 CIE Chromaticity Diagram in a region defined by ccx, ccy coordinates of (0.226, 0.295), (0.295, 0.298), (0.375, 0.472), (0.506, 0.303), (0.226, 0.295); and
a second group of at least one red solid state emitter that emits light having a dominant wavelength in the red color range.

24. The light emitting device of claim 23, wherein the blue LED emits light having a peak wavelength of less than 455 nanometers.

25. The light emitting device of claim 24, wherein the dominant wavelength of the second luminescent material is greater than the dominant wavelength of the red solid state emitter.

26. The light emitting device of claim 25, wherein the color temperature of the light emitted by the combination of the at least one blue-shifted-yellow solid state emitter and the at least one red LED is less than 5500K.

27. The light emitting device of claim 26, wherein the second luminescent materials comprise less than ten percent by weight of a sum of the first and second luminescent materials.

28. The light emitting device of claim 27, wherein the light emitted by the combination of the first group of at least one blue-shifted-yellow solid state emitter and the second group of at least one red solid state emitter has a color point that is within a 4-step MacAdam ellipse of a black body locus on the 1931 CIE Chromaticity Diagram.

29. A light emitting device, comprising:
a light emitting diode (“LED”) that, when excited, emits visible light, and an associated luminophoric medium that includes at least a first luminescent material that, when excited by light from the LED, emits light having a dominant wavelength in the red color range,
wherein the light emitted by the combination of the LED and all of the luminescent materials in the associated luminophoric medium has a color point that is both above the black body locus on the 1931 CIE Chromaticity Diagram and within a 10-step MacAdam ellipse of the black body locus.

30. The light emitting device of claim 29, wherein the associated luminophoric medium further includes a second luminescent material that, when excited by light from the LED, emits light having a dominant wavelength in the green color range.

31. The light emitting device of claim 30, wherein the associated luminophoric medium further includes a third luminescent material that, when excited by light from the LED, emits light having a dominant wavelength in the yellow color range.
